(19) United States
(12) Patent Application Publication
(10) Pub. No.: US 2018/0374893 A1
(43) Pub. Date: Dec. 27, 2018

(54) DIFFERENTIAL SENSING CELL DESIGN FOR STT MRAM

(71) Applicant: GLOBALFOUNDRIES Singapore Pte. Ltd., Singapore (SG)

(72) Inventors: Eng Huat TOH, Singapore (SG); Yinjie DING, Singapore (SG); Kangho LEE, Singapore (SG)

(21) Appl. No.: 15/630,534

(22) Filed: Jun. 22, 2017

(51) Int. Cl. H01L 27/22; H01L 43/08; H01L 43/12

(52) U.S. Cl. CPC H01L 27/222; H01L 43/12; H01L 43/08

(57) ABSTRACT

A method of forming a differential sensing STT MRAM design and the resulting device are provided. Embodiments include rows of programmable cells formed in a magnetoresistive random-access memory (MRAM) device, each row having a source line (SL); and rows of complimentary cells formed in the MRAM device, each row having a SL, wherein a SL of a row of programmable cells and a SL of a row of complimentary cells of a pair of rows form a merged SL.

### TECHNICAL FIELD

The present disclosure relates to semiconductor processing. In particular, the present disclosure relates to differential sensing bitcell design, and specifically, to spin-transfer torque magnetoresistive random-access memory (STT MRAM) bit cell design in the 40 nanometer (nm) technology node and beyond.

### BACKGROUND

With conventional source line//bit line (SL/BL) differential sensing bitcell layout, a programmable cell with a complimentary cell are written in opposite polarity for differential sensing. The programmable cell and complimentary cell are in proximity to one another, such as in a top and bottom position, to reduce variation. However, the resistance of the SL metal 1 (M1) layer, e.g., having a minimum width of about 40 nm, as well as the need for small cell size, limits the write current.

Similarly, local SL for SRAM architecture does not allow for true random access, only one bit can be accessed in one block for both reading and writing. In addition, only one cell is accessible in one block and the programmable cells and complimentary cells are not in proximity to each other resulting in more bit-to-bit variation and mismatch. Further, more circuitry is present which results in higher power consumption and the inability to read reliably.

A need therefore exists for methodology enabling improved differential sensing in MRAM cell architecture with true random access in and the related device.

### SUMMARY

Another aspect of the present disclosure is to provide differential sensing in a MRAM design with true random access, reduced bit-to-bit variation and improved write/read margin. In particular, with the present disclosure there is provided a merged SL pair to improve write/read margin by 5 to 20% and to reduce metal resistance up to 70%. True random access is achievable with the present disclosure's differential cell architecture and permits programmable cells and complimentary cells to be in close proximity to reduce bit-to-bit variation and mismatch resulting in improved read margin. Another aspect of the present disclosure is to provide differential sensing in STT MRAM bitcell architecture.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

Aspects of the present application include a device including rows of programmable cells formed in a MRAM device, each row having a SL; and rows of complimentary cells formed in the MRAM device, each row having a SL, wherein a SL of a row of programmable cells and a SL of a row of complimentary cells of a pair of rows form a merged SL.

Aspects include the row of programmable cells and the row of complimentary cells of the pair being proximate to one another. Additional aspects include the row of programmable cells and the row of complimentary cells of the pair are a mirror image of each other. Other aspects include the rows of the programmable cells and the complimentary cells alternate. Further aspects include the programmable cells having a first polarity and the complimentary cells having a second polarity opposite the first polarity. Yet other aspects include each row of the programmable cells and each row of the complimentary cells further include a BL. Yet further aspects include a plurality of word lines (WL) that run in a perpendicular direction relative to the rows of programmable cells and complimentary cells. Additional aspects include the MRAM device including a SRAM device. Another aspect includes the MRAM device including a STT MRAM device.

Another aspect of the present application includes a method including forming rows of programmable cells in a MRAM device, each row with a SL; forming rows of complimentary cells in the MRAM device, each row with a SL; and merging a SL of a row of programmable cells and a SL of a row of complimentary cells of a pair of rows to form a merged SL.

Additional aspects include forming the row of programmable cells and the row of complimentary cells of the pair proximate to one another. Other aspects include forming the row of programmable cells and the row of the complimentary cells of the pair as a mirror image of each other. Yet other aspects include forming the rows of programmable cells and complimentary cells as alternating rows. Another aspect includes forming the rows of programmable cells with a first polarity and the rows of the complimentary cells with a second polarity opposite the first polarity. Still other aspects include forming each row of the programmable cells and each row of the complimentary cells with a BL. Other aspects include forming a plurality of WL in a perpendicular direction relative to the rows of programmable and complimentary cells. Further aspects include the MRAM device including a static random SRAM device. Additional aspects include the MRAM device comprises a STT MRAM device.

Yet another aspect of the present disclosure includes a method including forming rows of programmable cells in a STT MRAM device, one or more of the programmable cells written in a first polarity and each row comprising a BL and a SL; forming rows of complimentary cells in the STT MRAM device, the complimentary cells written in a second polarity opposite the first polarity and each row comprising a BL and a SL; and merging a SL of a row of programmable cells and a SL of a row of complimentary cells of a pair of rows to form a merged SL.

Further aspects include forming the row of programmable cells and the row of complimentary cells of the pair proximate to one another and as a mirror image of each other.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1A schematically illustrates a top plan view of a STT MRAM differential sensing bitcell design, according to an exemplary embodiment;

FIG. 1B schematically illustrates a cross section view the STT MRAM differential sensing bitcell design of FIG. 1A along line A-A′; and

FIG. 2 schematically illustrates a top plan view of a STT MRAM voltage plan layout of a differential sensing cell design, according to an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problems associated with differential cell designs. The problem is solved, inter alia, by providing a merged SL per pair of programmable cells and complimentary cells, which provide true random access, reduced bit-to-bit variation and mismatch and improved write/read margin.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

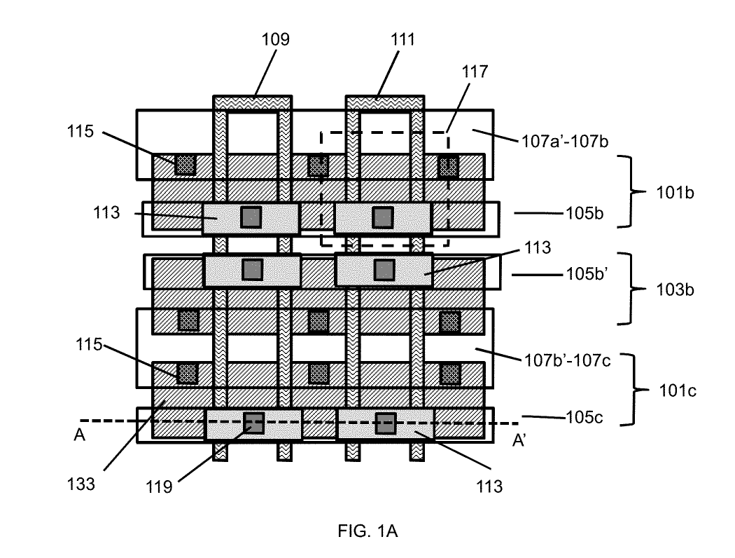

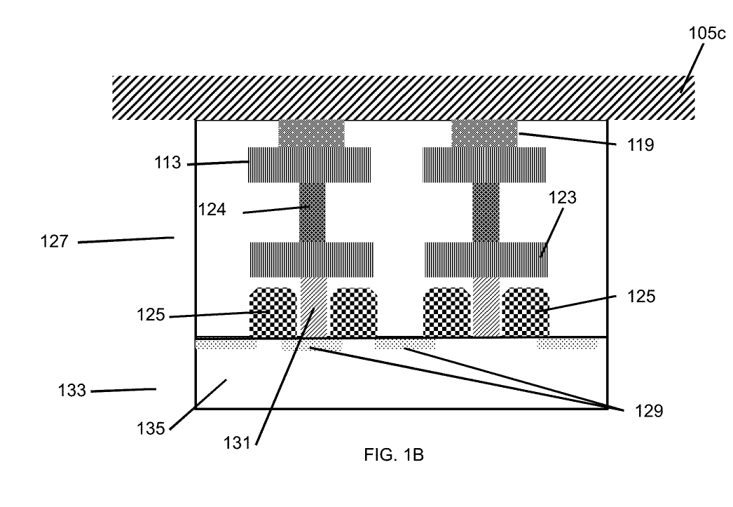

FIG. 1A schematically illustrates a top plan view of a STT MRAM differential sensing bitcell design, according to an exemplary embodiment. Adverting to FIG. 1A, alternating rows of programmable cells 101 and rows of complimentary cells 103 are formed in pairs, e.g., 101a and 103a, 101b and 103b, 101c and 103c, etc., across the memory array. Each row of programmable cells 101 and complimentary cells 103 of a pair, e.g., 101b and 103b, are proximate to one another relative to a conventional design, are a mirror image of each other and the programmable cells 101 and complimentary cells 103 have opposite polarities.

Each row of programmable cells 101 and complimentary cells 103 includes a BL 105, e.g., 105b and 105b′, respectively. In a conventional differential cell design, each programmable cell 101 and complimentary cell 103 also includes a SL 107; however, in this differential sensing bitcell design a row of programmable cells 101, e.g., 101c, and a row of complimentary cells 103, e.g., 103b, share a merged SL 107, e.g., SL 107b′-1017c, as depicted in FIG. 1A. Consequently, the increased width of the metal of the merged SL pairs, e.g., SL 107b′-107c, results in a reduced resistance in the MRAM device relative to a conventional design.

In addition, the STT MRAM layout of FIG. 1A also includes WLs 109 (W0) and 111 (W1) that run in a perpendicular direction relative to the rows of programmable cells 101 and complimentary cells 103 and a series of metal pads 113 and contacts 115 that connect active area 133 (FIG. 1B) to the upper metal layers, including M1 123 (FIG. 1B) or metal pads 113.

FIG. 1B schematically illustrates a cross section view of the STT MRAM differential sensing bitcell design of FIG. 1A along line A-A′. The BL 105 represents represent several layers of metal connected to and positioned above the active layer 133. The MTJ stack 119, in this example, is shown between M2 113 and BL 105c. The MTJ stack 119 can be positioned elsewhere. The active area 133 includes M1 123, vias 124, and interlayer dielectric (ILD) 127 over gates 125. M1 123 is in contact with source/drain regions 129 in substrate 135 (where the transistor is built) by way of contacts 131.

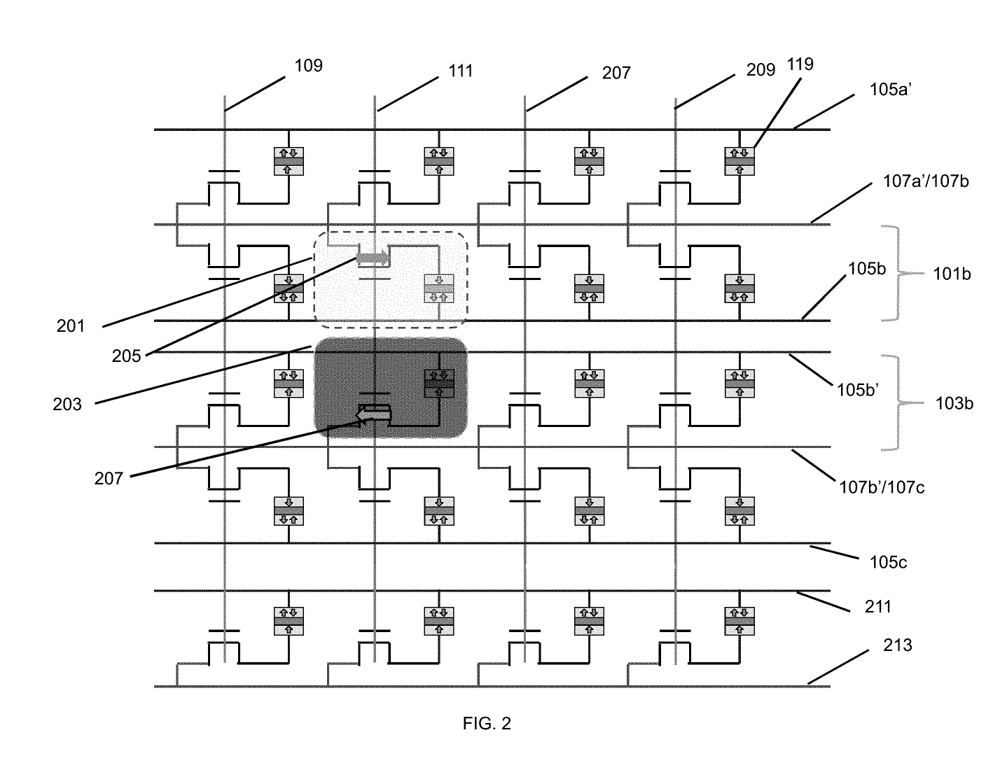

FIG. 2 schematically illustrates a top plan view of a STT MRAM voltage plan layout of a differential sensing cell design, according to an exemplary embodiment. Adverting to FIG. 2, target cells 201 and 203 of the programmable cells 101b and complimentary cells 103b of FIG. 1A, respectively, are written in opposite polarity represented by directional arrows 205 (parallel-to-anti-parallel (P-AP)) and 207 (AP-P). As in FIG. 1A, the merged SL pairs 107a′-107b and 107b′-107c form part of the programmable cells 101b and complimentary cells 103a (not shown for illustrative convenience) and complimentary cells 103b and programmable cells 101c, respectively. WLs 109 (WL0), 111 (WL1), 207 (WL2), and 209 (WL511) run perpendicular through the programmable and complimentary cells 101 and 103, respectively, and represent the 512 WLs (WL0-WL511) of each column of programmable and complimentary cells 101 and 103, respectively, of the STT MRAM design. Again, each row of programmable cells 101 and complimentary cells 103 includes a BL 105, e.g., 105b and 105b′ and BL 211 and SL 213 represent BL 127 and SL 127, respectively, of the 128 SL//BL. In addition, each transistor of the STT MRAM design includes MTJ structure 119. With the layout design architecture represented in FIG. 2, access to other BLs at the same time is possible, which is an improvement over conventional devices wherein only one bit is accessible in a block. The close proximity of the target cells 201 and 203 of the programmable and complimentary cells 101b and 103b, respectively, e.g., 5 to 200 nm apart depending on the technology and design rule, reduces the bit-to-bit variation/mismatch and improve write/read margin.

In accordance with the exemplary embodiment each row each row of programmable cells and complimentary cells contains a plurality of memory cells. Each intersection of a WL indicates a memory cell. Thus, each memory cell in a row can be written in 1 or 0 state. For example, WL 109 may be in a 0 state and WLs 111, 207, and 209 can be in 1 state and so on.

Table 1 below represents a bias table in accordance with an exemplary embodiment. The numerical values for the programmable cells and complimentary cells are expressed in volts (V). The differential sensing bitcell with merged SL provides for better write/read margin, as indicated by the V values in Table 1.

TABLE 1

| | | PROGRAMABLE | | COMPLIMENTARY | | |
|---|---|---|---|---|---|---|
| | | CELLS | | CELLS | | |
| | | | SL(Y − 1)′-Y | | SLY′(Y + 1) & | |
| | WLX | BLY | & BL(Y − 1)′ | BLY′ | BL(Y + 1) | Other |
| | (V) | (V) | (V) | (V) | (V) | WL/BL/SL |
| P-AP Write | 1.4-1.8 | 0 | 0.6-1.0 | 0.4-0.8 | 0 | 0 |
| AP-P Write | 1.4-1.8 | 0.4-0.8 | 0 | 0 | 0.6-1.0 | 0 |
| Read | 0.8-1.3 | 0.1-0.2 | 0 | 0.1-0.2 | 0 | 0 |

The embodiments of the present disclosure can achieve several technical effects, including lower resistance, reduced bit-to-bit variation and mismatch for improved read margin relative to conventional SL//BL differential cell design. The present disclosure enjoys industrial applicability in any of various industrial applications, e.g., microprocessors, smart phones, mobile phones, cellular handsets, set-top boxes, DVD recorders and players, automotive navigation, printers and peripherals, networking and telecom equipment, gaming systems, digital cameras, and power conversion applications. The present disclosure therefore enjoys industrial applicability in any of various types of MRAM devices in the 40 nm technology node and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A device comprising:
rows of programmable cells formed in a magnetoresistive random-access memory (MRAM) device, each row having a source line (SL); and
rows of complimentary cells formed in the MRAM device, each row having a SL,
wherein a SL of a row of programmable cells and a SL of a row of complimentary cells of a pair of rows form a merged SL, and
wherein the programmable cells comprise a first polarity and the complimentary cells comprise a second polarity opposite the first polarity.

2. The device according to claim 1, wherein the row of programmable cells and the row of complimentary cells of the pair are proximate to one another.

3. The device according to claim 1, wherein the row of programmable cells and the row of complimentary cells of the pair are a mirror image of each other.

4. The device according to claim 1, wherein the rows of the programmable cells and the complimentary cells alternate.

5. (canceled)

6. The device according to claim 1, wherein each row of the programmable cells and each row of the complimentary cells further comprises a bit line (BL).

7. The device according to claim 1, further comprising a plurality of word lines (WL) that run in a perpendicular direction relative to the rows of programmable cells and complimentary cells.

8. (canceled)

9. The device according to claim 1, wherein the MRAM device comprises a spin-transfer torque (STT) MRAM device.

10. A method comprising:
forming rows of programmable cells in a magnetoresistive random-access memory (MRAM) device, each row with a source line (SL);
forming rows of complimentary cells in the MRAM device, each row with a SL; and
merging a SL of a row of programmable cells and a SL of a row of complimentary cells of a pair of rows to form a merged SL,
wherein the rows of programmable cells are formed with a first polarity and the rows of the complimentary cells are formed with a second polarity opposite the first polarity.

11. The method according to claim 10, comprising forming the row of programmable cells and the row of complimentary cells of the pair proximate to one another.

12. The method according to claim 10, comprising forming the row of programmable cells and the row of the complimentary cells of the pair as a mirror image of each other.

13. The method according to claim 10, comprising forming the rows of programmable cells and complimentary cells as alternating rows.

14. (canceled)

15. The method according to claim 10, further comprising forming each row of the programmable cells and each row of the complimentary cells with a bit line (BL).

16. The method according to claim 10, further comprising forming a plurality of word lines (WL) in a perpendicular direction relative to the rows of programmable and complimentary cells.

17. (canceled)

18. The method according to claim 10, wherein the MRAM device comprises a spin-transfer torque (STT) MRAM device.

19. A method comprising:
forming rows of programmable cells in a spin-transfer torque magnetoresistive random-access memory (STT MRAM) device, wherein one or more of the programmable cells written in a first polarity and each row comprising a bit line (BL) and a source line (SL);
forming rows of complimentary cells in the STT MRAM device, wherein one or more of complimentary cells written in a second polarity opposite the first polarity and each row comprising a BL and a SL; and
merging a SL of a row of programmable cells and a SL of a row of complimentary cells of a pair of rows to form a merged SL.

20. The method according to claim 19, comprising forming the row of programmable cells and the row of complimentary cells of the pair proximate to one another and as a mirror image of each other.
